(19) United States
(12) Patent Application Publication
(10) Pub. No.: US 2026/0086466 A1
(43) Pub. Date: Mar. 26, 2026

(54) LITHOGRAPHIC APPARATUS AND METHOD

(71) Applicant: ASML NETHERLANDS B.V., Veldhoven (NL)

(72) Inventors: Koos VAN BERKEL, Waalre (NL); Martinus Hendrikus Antonius LEENDERS, Rhoon (NL)

(73) Assignee: ASML NETHERLANDS B.V., Veldhoven (NL)

(21) Appl. No.: 19/112,529

(22) PCT Filed: Sep. 11, 2023
(86) PCT No.: PCT/EP2023/074882

§ 371 Date: Mar. 17, 2025

(30) Foreign Application Priority Data
Oct. 19, 2022 (EP) 22202403.6

(51) Int. Cl. G03F 7/00; B23K 26/046; B23K 26/06; B23K 26/082; B23K 26/402; B23K 26/55; B23K 103/00; G02B 26/08

(52) U.S. Cl. CPC G03F 7/70266; B23K 26/046; B23K 26/0643; B23K 26/082; B23K 26/402; B23K 26/55; G02B 26/0825; G03F 7/70316; G03F 7/70508; G03F 7/70516; G03F 7/70525; G03F 7/70825; G03F 7/7085; B23K 2103/54

(57) ABSTRACT

A lithographic apparatus including a reflector for reflecting radiation. The reflector has a body, a reflective surface arranged on the body, and a channel formed in the body for conveying a fluid. The lithographic apparatus includes a controller configured to adjust a pressure of the fluid in the channel to control a deformation of the reflective surface and thereby control an overlay of the lithographic apparatus.

### CROSS-REFERENCE TO RELATED APPLICATIONS

This application claims priority of EP application 22202403.6 which was filed on Oct. 19, 2022 and which is incorporated herein in its entirety by reference.

### FIELD

The present invention relates to a lithographic apparatus and method for controlling overlay.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern at a patterning device (e.g., a mask) onto a layer of radiation-sensitive material (resist) provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

A lithographic process typically involves performing multiple exposures across consecutive substrate layers to form a desired structure. An accuracy with which a newly projected pattern aligns with a previously projected pattern is referred to in the art as overlay. Throughout a device manufacturing process, overlay errors may arise from a number of different sources. A first known method of controlling overlay involves changing a position of one or more reflectors within the lithographic apparatus. However, the first known method of controlling overlay is only capable of reducing lower order overlay errors (e.g. overlay errors corresponding to lower order field dependencies such as offset or tilts). That is, the first known method is incapable of reducing higher order overlay errors (e.g. overlay errors corresponding to higher order field dependencies such as higher order polynomial deformation profiles). A second known method of controlling overlay involves heating one or more reflectors of the lithographic apparatus to introduce controlled thermal deformation of the one or more reflectors. However, the reflectors, particularly EUV reflectors, may be relatively large and bulky objects that are relatively slow to thermally deform in response to changes in temperature. As such, the second known method of controlling overlay is incapable of performing fast, high frequency overlay corrections due to the relatively long thermal setting time of the reflectors.

Known lithographic apparatus and methods may be limited in their ability to correct for overlay errors. It is desirable to provide a lithographic apparatus and method that obviates or mitigates one or more of the problems of the prior art, whether identified herein or elsewhere.

### SUMMARY

According to a first aspect of the present disclosure, there is provided a lithographic apparatus comprising a reflector for reflecting radiation. The reflector comprises a body, a reflective surface arranged on the body, and a channel formed in the body for conveying a fluid. The lithographic apparatus comprises a controller configured to adjust a pressure of the fluid in the channel to control a deformation of the reflective surface and thereby control an overlay of the lithographic apparatus.

The lithographic apparatus of the present disclosure is capable of reducing higher order optical errors (e.g. overlay errors corresponding to higher order field dependencies such as higher order polynomial deformation profiles). The lithographic apparatus of the present disclosure is advantageously capable of performing fast, high spatial-frequency deformations to the reflective surface, thereby allowing for fast, high spatial-frequency overlay corrections to take place. High spatial-frequency deformations to the reflective surface may refer to at least a fourth order polynomial deformation profile applied to the reflective surface by adjustment of the pressure of the fluid. High spatial-frequency overlay corrections may refer to at least third order polynomial overlay shapes or errors.

The reflective surface and the body may be integrally formed.

The reflective surface and the body may be separately formed. The body may be configured to support the reflective surface. The body may form part of a clamp configured to secure the reflective surface.

The channel may form part of a cooling system configured to cool the reflective surface. The controller may be retrofit to an existing cooling system. This advantageously increases a utility of the cooling system. That is, the cooling system is able to cool the reflective surface (thereby reducing unwanted thermal deformations) whilst also controlling a pressure-based deformation of the reflective surface (thereby imparting the radiation with desired characteristics upon reflection from the reflective surface).

Adjusting the pressure of the fluid may comprise adjusting a flow rate of the fluid.

A depth of the channel relative to the reflective surface may vary along a length of the channel.

A varying depth of channel advantageously introduces a varying stiffness profile of the body between the channel and the reflective surface, thereby allowing a greater variety of deformations of the reflective surface to be applied.

The body of the reflector may comprise a plurality of channels. A depth of a first channel relative to the reflective surface may vary along a length of the first channel in a way that is different to how a depth of a second channel relative to the reflective surface varies along a length of the second channels. That is, different channels may have different depth profiles relative to the reflective surface.

The channel may be one of a plurality of channels formed in the body for conveying the fluid. At least two of the channels may have different cross-sectional shapes. Cross-sectional shapes of at least two of the channels may have different orientations relative to the reflective surface.

Using channels having different cross-sectional shapes and/or orientations advantageously introduces a varying force profile applied to the reflective surface by the pressure of the fluid flowing through the first and second channels to the reflective surface, thereby allowing a greater variety of deformations of the reflective surface to be applied. Using channels having different cross-sectional shapes and/or orientations advantageously allows for flow speed and restriction of the fluid in the first and second channels to be maintained at a desired level whilst being able to vary the force profile applied to the reflective surface by the pressure of the fluid flowing through the first and second channels.

Depths of the channels relative to the reflective surface along lengths of the channels and the cross-sectional shapes of the channels may be designed such that the controller is operable to adjust the pressure of the fluid in the channels to apply at least a fourth order polynomial deformation profile to the reflective surface.

Applying a fourth order polynomial deformation profile to the reflective surface advantageously allows for higher order optical errors (e.g. overlay errors corresponding to higher order field dependencies such as higher order polynomial deformation profiles (e.g. 3^{rd} order polynomial overlay errors)) to be reduced by the controller.

The controller may be configured to independently adjust the pressures of the fluid in at least two of the plurality of channels to control the deformation of the reflective surface.

Independently adjusting the pressures of the fluid in at least two of the plurality of channels advantageously allows different deformation profiles to be applied to the reflective surface thereby allowing greater control of the overlay of the lithographic apparatus.

The controller may comprise a plurality of sub-controllers. Different sub-controllers may be configured to adjust the pressure of the fluid in different channels or different groups of channels.

The lithographic apparatus may comprise an inlet conduit configured to provide the fluid to the channel. The lithographic apparatus may comprise an outlet conduit configured to receive the fluid from the channel. The lithographic apparatus may comprise a flow restrictor arranged on the outlet conduit.

The controller may be configured to adjust a flow rate of the fluid and the action of the flow restrictor may adjust the pressure of the fluid in the channel.

The lithographic apparatus may comprise a pressure sensor configured to detect a pressure of the fluid in the channel. The controller may be configured to use data provided by the pressure sensor to control a pressure of the fluid in the channel.

The flow restrictor may comprise a pressure valve. The controller may be configured to control the pressure valve to adjust the pressure of the fluid in the channel.

The pressure valve advantageously provides rapid changes in pressure by the controller, thereby providing rapid changes in the deformation of the reflective surface.

The pressure valve may comprise a piezoelectric element configured to grip the outlet conduit.

The lithographic apparatus may comprise an optical sensor configured to detect at least a portion of the radiation reflected by the reflective surface. The controller may be configured to receive optical measurement data from the optical sensor and use the optical measurement data to control the deformation of the reflective surface.

The optical sensor advantageously allows feedback control of the radiation such that the radiation is imparted with desired characteristics upon reflection from the reflective surface despite changes in operating conditions. The optical sensor advantageously allows a calibration to be performed in which the effects of pressure adjustments made by the controller on the characteristics of the radiation reflected by the reflective surface (e.g. a wavefront of the radiation) are determined and/or modelled. The optical sensor may comprise one or more interferometric wavefront sensors.

The lithographic apparatus may comprise an actuator configured to adjust a position and/or an orientation of the reflector.

The actuator advantageously provides additional control when imparting the radiation with desired characteristics upon reflection from the reflective surface.

The actuator may be configured to provide movement of the reflector within six rigid body degrees of freedom (e.g. three linear degrees of freedom and three rotational degrees of freedom).

The reflective surface may be partially spherical.

The lithographic apparatus may comprise a heater configured to heat the reflector and introduce controlled thermal deformation of the reflective surface and thereby provide additional control when imparting the radiation with desired characteristics upon reflection from the reflective surface.

The lithographic apparatus may comprise an illumination system configured to condition the radiation beam. The lithographic apparatus may comprise a support structure constructed to support a patterning device, the patterning device being capable of imparting the radiation beam with a pattern in its cross-section to form a patterned radiation beam. The lithographic apparatus may comprise a substrate table constructed to hold a substrate. The lithographic apparatus may comprise a projection system configured to project the patterned radiation beam onto the substrate. The reflector may be a mirror in the projection system.

The lithographic apparatus may comprise an illumination system configured to condition the radiation beam. The lithographic apparatus may comprise a support structure constructed to support a patterning device, the patterning device being capable of imparting the radiation beam with a pattern in its cross-section to form a patterned radiation beam. The lithographic apparatus may comprise a substrate table constructed to hold a substrate. The lithographic apparatus may comprise a projection system configured to project the patterned radiation beam onto the substrate. The reflective surface may form part of the patterning device. The body may form part of the support structure.

According to a second aspect of the present disclosure, there is provided a method comprising providing a flow of fluid through a channel formed in a body on which a reflective surface of a lithographic apparatus is arranged. The method comprises adjusting a pressure of the fluid to control a deformation of the reflective surface and thereby control an overlay of the lithographic apparatus. The method comprises reflecting radiation from the reflective surface.

A depth of the channel may vary relative to the reflective surface along a length of the channel.

The channel may be one of a plurality of channels formed in the body for conveying the fluid. The method may comprise providing the flow of fluid through at least two channels having different cross-sectional shapes. The method may comprise providing the flow of fluid through at least two channels having cross-sectional shapes that have different orientations relative to the reflective surface.

The method may comprise adjusting the pressure of the fluid in the channels to apply at least a fourth order polynomial deformation profile to the reflective surface.

The method may comprise independently adjusting the pressures of the fluid in at least two of the plurality of channels to control the deformation of the reflective surface.

The method may comprise adjusting a position and/or an orientation of the reflective surface.

According to a third aspect of the present disclosure, there is provided a method of manufacturing the body of the reflector of the lithographic apparatus of the first aspect, comprising performing laser ablation to form the channel.

Laser ablation advantageously provides fine control of the depth profile and cross-sectional shape of the channel, thereby allowing a greater variety of depth profiles and cross-sectional shapes to be formed.

Performing laser ablation to form the channel may comprise varying a depth of the channel relative to the reflective surface along a length of the channel.

The method of manufacturing the body of the reflector may comprise performing laser ablation to form at least two channels having different cross-sectional shapes.

The method of manufacturing the body of the reflector may comprise performing laser ablation to form at least two channels having cross-sectional shapes that have different orientations relative to the reflective surface.

### BRIEF DESCRIPTION OF THE DRAWINGS

Embodiments of the invention will now be described, by way of example only, with reference to the accompanying schematic drawings, in which:

FIG. 1 schematically depicts a lithographic system comprising a lithographic apparatus, a radiation source, a reflector and a controller in accordance with the present disclosure.

FIG. 2 schematically depicts a cross-sectional view of a reflector in accordance with the present disclosure.

FIG. 3 schematically depicts a cross-sectional view of a reflector comprising a plurality of channels in accordance with the present disclosure.

FIG. 4 shows a graph of that demonstrates the ability of the reflector and controller of the present disclosure to control a third order field plane variation of overlay compared to a known method.

FIG. 5 shows a flowchart of a method in accordance with the present disclosure.

### DETAILED DESCRIPTION

FIG. 1 shows a lithographic system comprising a radiation source SO, a lithographic apparatus LA, a reflector MA, MT, 13, 14 and a controller 100 in accordance with the present disclosure. The radiation source SO is configured to generate an EUV radiation beam B and to supply the EUV radiation beam B to the lithographic apparatus LA. The lithographic apparatus LA comprises an illumination system IL, a support structure MT configured to support a patterning device MA (e.g., a mask), a projection system PS and a substrate table WT configured to support a substrate W.

The illumination system IL is configured to condition the EUV radiation beam B before the EUV radiation beam B is incident upon the patterning device MA. Thereto, the illumination system IL may include a faceted field mirror device 10 and a faceted pupil mirror device 11. The faceted field mirror device 10 and faceted pupil mirror device 11 together provide the EUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV radiation beam B interacts with the patterning device MA. As a result of this interaction, a patterned EUV radiation beam B′ is generated. The projection system PS is configured to project the patterned EUV radiation beam B′ onto the substrate W. For that purpose, the projection system PS may comprise a plurality of mirrors 13,14 which are configured to project the patterned EUV radiation beam B′ onto the substrate W held by the substrate table WT. The projection system PS may apply a reduction factor to the patterned EUV radiation beam B′, thus forming an image with features that are smaller than corresponding features on the patterning device MA. For example, a reduction factor of 4 or 8 may be applied. Although the projection system PS is illustrated as having only two mirrors 13, 14 in FIG. 1, the projection system PS may include a different number of mirrors (e.g. six or eight mirrors).

The substrate W may include previously formed patterns. Where this is the case, the lithographic apparatus LA aligns the image, formed by the patterned EUV radiation beam B', with a pattern previously formed on the substrate W.

A relative vacuum, i.e. a small amount of gas (e.g. hydrogen) at a pressure well below atmospheric pressure, may be provided in the radiation source SO, in the illumination system IL, and/or in the projection system PS.

The radiation source SO may be a laser produced plasma (LPP) source, a discharge produced plasma (DPP) source, a free electron laser (FEL) or any other radiation source that is capable of generating EUV radiation.

The lithographic apparatus LA comprises a reflector MA-MT, 13, 14 for reflecting radiation B, B′. The reflector may be the patterning device MA and the support structure MT. The reflector may be one of the mirrors 13, 14 in the projection system PS. The lithographic apparatus LA may comprise a plurality of reflectors in accordance with the present disclosure. In the example of FIG. 1, the lithographic apparatus LA comprises three reflectors MA-MT, 13, 14 in accordance with the present disclosure. Each reflector comprises a body, a reflective surface arranged on the body and a channel formed in the body for conveying a fluid. The components of reflectors 13, 14 in accordance with the present disclosure are shown in greater detail in FIGS. 2 and 3. In the example of the patterning device MA and support structure MT, the reflective surface forms part of the patterning device MA and the body forms part of the support structure MT. For example, the body may form part of an electrostatic clamp of the support structure MT that is configured to secure the patterning device MA. In the example of the patterning device MA and support structure MT, the reflective surface and the body may be considered to be separately formed components. Alternatively, the reflective surface and the body may be integrally formed such as for example, one or more of the mirrors 13, 14 in the projection system PS.

The lithographic apparatus LA further comprises a controller 100 configured to adjust a pressure of the fluid in the channel of the reflector MA-MT, 13, 14 to control a deformation of the reflective surface and thereby control an overlay of the lithographic apparatus LA. Deformation of the reflective surface may result from a pressure difference between the pressure of the fluid in the channels and the pressure of the vacuum environment in which the reflective surface is located. For example, the pressure of the fluid in the channels may be about 300 mbar whilst the pressure of the environment in which the reflective surface is located may be about 5 Pa. In the example of FIG. 1, the channel (not shown) forms part of a cooling system 110 configured to cool the reflective surface of the reflector MA-MT, 13, 14. The controller 100 may be retrofit to an existing cooling system of a lithographic apparatus LA.

FIG. 2 schematically depicts a cross-sectional view of a reflector 14 in accordance with the present disclosure. Cartesian coordinates X, Y, Z are provided in FIGS. 2 and 3 to aid understanding of the reflectors 13, 14. In the example of FIG. 2, the reflector 14 corresponds to the second shown mirror 14 of the projection system PS of the lithographic apparatus LA of FIG. 1. The reflector 14 comprises a body 200, a reflective surface 210 arranged on the body 200, and a channel 220 formed in the body 200 for conveying a fluid. The reflective surface 210 may configured to reflect EUV radiation. The reflector 14 may comprise a material having a relatively low coefficient of thermal expansion such as, for example, titania silicate glass (e.g. ULETM manufactured by Corning Incorporated), Zerodur™ or cordierite.

The reflective surface 210 may have a reflectivity of about 70% or less. Therefore the reflective surface 210 absorbs a significant amount of energy from the radiation beam B′ when the lithographic apparatus LA is operating. The reflective surface 210 may experience a non-uniform increase in temperature across an area of the reflective surface 210, particularly if the illumination mode (e.g. dipole illumination) of the illumination system IL is set such that the radiation beam B′ is unevenly distributed across different regions of the reflective surface 210. The non-uniform temperature rise in the reflector 14 can lead to a significant deformation of the reflective surface 210. Even though the deformation of the reflective surface 210 may be very small in absolute terms, due to the extreme precision required to manufacture devices with small feature sizes, such deformation can lead to imaging errors. As such, the lithographic apparatus LA is provided with a cooling system 110 configured to remove heat energy from the reflectors MA-MT, 13, 14 and thereby reduce unwanted thermal deformations of the reflectors MA-MT, 13, 14.

The cooling system 110 comprises channels 220 that run through bodies 200 of the reflectors MA-MT, 13, 14. In the example of FIG. 2, the channel 220 is connected to an inlet conduit 230 configured to provide the fluid to the channel 220 and an outlet conduit 240 configured to receive the fluid from the channel 220. The inlet conduit 230 may form part of an input manifold configured to provide the fluid to a plurality of channels 220 in the body 200 and the outlet conduit 240 may form part of an output manifold configured to receive the fluid from the plurality of channels 220 in the body 200. The channels 220 may be arranged to increase a thermal transfer between the body 200 and the fluid flowing through the channels 220. The channels 220 may be formed directly in the material of the body 200 using laser ablation. The cooling system 110 may comprise a temperature conditioning system to ensure that the fluid supplied to the channels 220 is at a desired temperature. The fluid may, for example, be water. Using water may be advantageous because water has a relatively high thermal capacity so a relatively low mass flow rate can provide a relatively large heat transfer capacity. As another example, the fluid may be carbon dioxide. Using carbon dioxide may be advantageous because carbon dioxide can be supplied as a liquid (under pressure) so that it evaporates within the channels 220 in the regions of higher temperature. The latent heat of evaporation therefore increases the heat transfer capacity of the fluid. For a given heat load, the required mass flow can be much lower than with water, thereby reducing flow-induced vibrations of the reflective surface 210.

A depth of the channel 220 relative to the reflective surface 210 varies along a length of the channel 220. That is, at a first position along a length of the channel 220, the channel 220 has a first depth 221 relative to the reflective surface 210, and at a second position along the length of the channel 220, the channel 220 has a second depth 222 relative to the reflective surface 210. The first and second depths 221, 222 are different. In the example of FIG. 2, the depth of the channel 220 relative to the reflective surface 210 varies along the length of the channel 220 such that the channel 220 forms an umbrella-like shape. That is, the further away from a centre of the length of the channel 220, the larger the depth of the channel 220 relative to the reflective surface 210 becomes. The depth of the channel 220 may vary in other ways to form other shapes. In the example of FIG. 2, only a single channel 220 is shown. However, the reflector 14 may comprise a plurality of channels 220, and different channels 220 within the plurality of channels 220 may have different depth profiles. In general, the depth profile of the channel 220 may be selected to create a desired stiffness profile within the portion of the body 200 located between the channel 220 and the reflective surface 210. A depth 221, 222 of the channel 220 relative to the reflective surface 210 may be about 0.5 mm or more. A depth 221, 222 of the channel 220 relative to the reflective surface 210 may be about 30 mm or less.

FIG. 3 schematically depicts a cross-sectional view of a reflector 13 comprising a plurality of channels 320-324 in accordance with the present disclosure. In the example of FIG. 3, the reflector 13 corresponds to the first shown mirror 13 of the projection system PS of the lithographic apparatus LA of FIG. 1. The viewing direction of the cross-sectional view of FIG. 3 corresponds to a 90° rotation of the viewing direction of the cross-sectional view of FIG. 2 in that FIG. 2 shows a side view of the channel 220 whereas FIG. 3 shows a head-on view of the channels 320-324. The number of channels 320-324 may at least partially depend upon a size of the reflector 13 and/or a separation between adjacent channels 320-324. For example, there may be between 10 and 100 channels 320-324 provided in the body 300. For example, there may be between 20 and 60 channels 320-324 provided in the body 300. For example, there may be about 40 channels provided in the body 300.

At least two of the channels 320-324 may have different cross-sectional shapes. In the example of FIG. 3, three of the channels have elliptical cross-sectional shapes 320, 322, 324 and two of the channels have circular cross-sectional shapes 321, 323. The channels 320-324 may have other cross-sectional shapes. For example, the channels 320-324, may have square, rectangular, triangular, etc., cross-sectional shapes. If the cross-sectional shape of a channel 320-324 is not circular, then a diameter of the channel may be taken to be the largest dimension of the cross-sectional shape. If the diameter of a channel 320-324 is relatively small then the flow resistance may be relatively high, thereby requiring a greater pressure difference to achieve a sufficient mass flow rate of the fluid. If the diameter of a channel 320-324 is too large it may be difficult to achieve uniform cooling of the reflective surface 310. The diameter of a channel 220, 320-324 may be about 0.1 mm or more. The diameter of a channel 220, 320-324 may be about 10 mm or less.

The cross-sectional shapes of at least two of the channels 320-324 may have different orientations relative to the reflective surface 310. In the example of FIG. 3, two of the elliptical channels 320, 324 are orientated such that their major axes 325, 326 are substantially perpendicular to the reflective surface 310 whereas one of the elliptical channels 322 is orientated such that its major axis 327 is substantially parallel to the reflective surface 310. That is, two of the elliptical channels 320, 324 are orientated at 90° relative to the other elliptical channel 322. The cross-sectional shapes of the channels 320, 322, 324 may have other orientations relative to the reflective surface 310 and/or each other.

In general, the cross-sectional shapes and/or the orientations of the cross-sectional shapes of the channels 320-324 may be selected to create a desired force profile that is actionable by adjusting a pressure of the fluid in the channels 320-324 and/or to create a desired fluid flow restriction by the channels 320-324. For example, aspect ratios of cross-sectional shapes of the channels 320-324 may be selected to create a desired force profile that is actionable by adjusting a pressure of the fluid in the channels 320-324 and/or to create a desired fluid flow restriction by the channels 320-324. In the example of FIG. 3, a first diameter 327 of the cross-sectional shapes of the channels 320-324 along a first direction X is selected to at least partially determine a desired force profile that is actionable by adjusting a pressure of the fluid in the channels 320-324. The first direction X is substantially parallel to the reflective surface 210. Increasing the first diameter 327 may increase a force applied to the reflective surface 210 by the pressure of the fluid in the channels 320-324. A second diameter 325, 326 of the cross-sectional shapes of the channels 320-324 along a second direction Z that is substantially perpendicular to the first direction X is selected to at least partially determine a desired fluid flow restriction by the channels 320-324. The second direction Z is substantially perpendicular to the reflective surface 210. With reference to FIGS. 1-3, in general the depth profiles 221, 222 and/or the cross-sectional shapes and/or the orientations of the cross-sectional shapes of the channels 320-324 may be selected to at least partially determine the deformation profile of the reflective surface 310 (and thereby the overlay of the lithographic apparatus LA) whilst also maintaining a desired cooling power of the cooling system 110. The depths 221, 222 of the channels 220 relative to the reflective surface 210 may be about 2 mm or more. The depths 221, 222 of the channels 220 relative to the reflective surface 210 may be about 10 mm or less.

Referring to FIGS. 1 and 2, the lithographic apparatus LA comprises a flow restrictor 250 arranged on the outlet conduit 240. In the case of a simple flow restrictor, the controller 100 may adjust a flow rate of the fluid and the action of the flow restrictor 250 may adjust the pressure of the fluid in the channel. The lithographic apparatus LA may comprise a pressure sensor (not shown) configured to detect a pressure of the fluid in the channel 220, 320-324. The controller 100 may be configured to use data provided by the pressure sensor to control a pressure of the fluid in the channel 220, 320-324. In the example of FIG. 2, the flow restrictor is a pressure valve 250. The controller 100 is configured to control the pressure valve 250 to adjust the pressure of the fluid in the channel 220. The pressure valve 250 may comprise a piezoelectric element configured to apply an adjustable grip or ‘pinch’ to the outlet conduit 240. The pressure valve 250 advantageously provides rapid changes in pressure by the controller 100, thereby providing rapid changes in the deformation of the reflective surface 210 and corresponding rapid control of the overlay of the lithographic apparatus LA. The controller 100 and the pressure valve 250 may be capable of changing the overlay of the lithographic apparatus LA in less than a second (e.g. about 100 ms, 200 ms or 500 ms). For example, the controller 100 and the pressure valve 250 may be capable of changing the overlay of the lithographic apparatus LA between lots of substrates W such that an overlay correction may be applied with respect to previously printed layers of the substrates W.

The lithographic apparatus LA comprises an optical sensor 120 configured to detect at least a portion of the radiation B′ reflected by the reflective surface MA-MT, 13, 14. The optical sensor 120 may comprise one or more interferometric wavefront sensors. The controller 100 is configured to receive optical measurement data from the optical sensor 120 and use the optical measurement data to control the deformation of the reflective surface MA-MT, 13, 14. The optical sensor 120 advantageously provides feedback control of the overlay of the lithographic apparatus LA. That is, the optical measurement data may be used by the controller 100 to control deformation of the reflective surface MA-MT, 13, 14 such that the radiation B′ is imparted with desired characteristics (e.g. a desired wavefront) upon reflection from the reflective surface MA-MT, 13, 14 despite changes in operating conditions. The optical sensor 120 advantageously allows a calibration to be performed in which the effects of pressure adjustments made by the controller 100 on the characteristics of the radiation B′ reflected by the reflective surface MA-MT, 13, 14 (e.g. a wavefront of the radiation) are determined and/or modelled.

Referring to FIGS. 1 and 3, the lithographic apparatus LA comprises an actuator 130 configured to adjust a position and/or an orientation of the reflector 13. The actuator 130 may be configured to move the reflector 13 such that a relative positioning between the reflective surface 310 and the radiation B′ changes. That is, different portions of the radiation B′ may be reflected by different portions of the reflective surface 310 after the reflector 13 has been moved by the actuator 130. The controller 100 may be configured to control the actuator 130 and thereby provide further control of the overlay of the lithographic apparatus LA. As shown in FIGS. 1 and 3, the reflective surface 310 of the first shown reflector 13 in the projection system PS is at least partially spherical. The partially spherical shape of the reflective surface 310 combined with the pressure-induced deformation of said shape may provide additional degrees of freedom in controlling the overlay of the lithographic apparatus LA compared to merely moving the reflectors 13, 14 with respect to the radiation beam B′.

The reflector 13 advantageously allows additional control of the overlay of the lithographic apparatus LA when imparting the radiation B′ with desired characteristics (e.g. a desired wavefront adjustment) upon reflection from the reflective surface 310.

The controller 100 is configured to adjust a pressure of the fluid in the channels 320-324 to control a deformation of the reflective surface 310 and thereby control an overlay of the lithographic apparatus LA. The shape of a wavefront of radiation B′ reflecting from the reflective surface 310 may be adjusted via deformation of the reflective surface 310. The wavefront may be adjusted such that an overlay error is reduced. The alignment of an image to its intended position on a substrate W may be referred to as overlay. Inaccuracies in the alignment of an image to its intended position on a substrate W may be referred to as overlay errors. The wavefront of the radiation B′ may be adjusted by the reflective surface 310 such that an overlay error is reduced.

Knowledge of the overlay of the lithographic apparatus LA may be determined via direct measurement (e.g. using a detector system such as the optical sensor 120 of FIG. 1), indirect measurement (e.g. performing a lithographic exposure in a resist and analysing the resist) and/or prediction (e.g. by inputting data into a computer model and executing the computer model). For example, data relating to overlay may be measured and input into a computer model. The computer model may be configured to receive data and perform calculations using that data in order to predict the overlay performance of the lithographic apparatus LA.

The overlay of the lithographic apparatus LA may be understood as a combination of different polynomials. A projection system PS of a lithographic apparatus LA comprises intrinsic optical aberrations due to optical components thereof having imperfections. Information relating to optical aberrations may be represented as a wavefront shape in a pupil plane of the lithographic apparatus LA. The wavefront shape may be expressed as a combination of polynomials, e.g. Zernike polynomials for optical systems comprising a circular pupil. Different polynomials may represent different types of optical aberrations. For example, a first Zernike polynomial may represent a tilt aberration whereas a second Zernike polynomial may represent a defocus aberration. Zernike polynomials are often categorized as being either odd (i.e. asymmetric) or even (i.e. symmetric). Different categories of Zernike polynomials may correspond to different projection system PS characteristics. For example, even Zernike polynomials may correspond to focus errors whereas odd Zernike polynomials may correspond to overlay errors. In general, the Zernike polynomials may be categorized in any desired manner. The dual index American National Standards Institute (ANSI) Zernike numbering scheme will be used in the following discussion of Zernikes.

Radiation B′ reaching different positions on the field plane of the lithographic apparatus LA (e.g. the surface of the substrate W) travels through different parts of the projection system PS and experiences different aberrations. That is, the wavefront shape at the pupil plane varies per position in the field plane. The variation across the field plane of overlay and/or a wavefront may be expressed by combinations of polynomials of different orders. For example, the field plane variation of a lower order Zernike (e.g. Z [1, 1], the Zernike that represents a horizontal tilt of the wavefront shape) may be expressed by a combination of different polynomials. Considering field plane variations of higher order polynomials may provide more information about overlay and/or optical aberrations present in the lithographic apparatus LA and/or how corrections may be induced within the lithographic apparatus LA via adjustments made to optical elements present within the lithographic apparatus LA. Field plane variations of overlay and/or a wavefront described by higher order polynomials may be more difficult to compensate for than field plane variations described by lower order polynomials.

The reflector MA-MT, 13, 14 and controller 100 of the present disclosure may be capable of performing fine adjustments (e.g. providing deformations of the reflective surface 210, 310 on the nanometre scale) of a wavefront that is incident upon the reflective surface. The fine adjustments of the wavefront that are made possible by the reflector MA-MT, 13, 14 and controller 100 of the present disclosure allow for a reduction of lithographic errors, and in particular overlay errors, that correspond to higher orders of field plane variations than known methods of reducing lithographic errors. For example, the reflector MA-MT, 13, 14 and controller 100 of the present disclosure may be used to apply a correction profile that compensates for at least 3^{rd} order field plane variations of overlay. For example, the reflector MA-MT, 13, 14 and controller 100 of the present disclosure may be used to apply a correction profile that compensates for at least 4^{th} order field plane variations of overlay. The reflector MA-MT, 13, 14 and controller 100 of the present disclosure may be used to apply a correction profile that compensates for field plane variations of Zernikes. The reflector MA-MT, 13, 14 and controller 100 of the present disclosure may be used to apply a correction profile that reduces overlay errors associated with at least 3^{rd} order field plane variations of a Zernike. The reflector MA-MT, 13, 14 and controller 100 of the present disclosure may be used to apply a correction profile that reduces overlay errors associated with at least 4^{th} order field plane variations of a Zernike. In general, it will be appreciated that the higher the order of field plane variations of polynomials (e.g. Zernike polynomials) that the reflector MA-MT, 13, 14 and controller 100 of the present disclosure are capable of compensating for, the more complicated the reflector MA-MT, 13, 14 may be to construct and operate. A balance between the complexity of the reflector MA-MT, 13, 14 and a correction capability of the controller 100 may be selected as desired.

The correction profile for the patterned radiation beam B′ may be determined based on knowledge of an overlay error. The correction profile is configured to reduce the overlay error when the correction profile is applied to the patterned radiation beam B′ by the reflective surface 210, 310 of the reflector MA-MT, 13, 14. The correction profile may comprise modifications of a wavefront required to reduce the overlay error. The reflector MA-MT, 13, 14 may be manufactured such that the reflective surface 210, 310 acquires a desired correction profile upon adjustment of the pressure of the fluid in the channels 220, 320-324 by the controller 100. That is, the reflector MA-MT, 13, 14 may be designed to compensate for field plane variations of a specific polynomial shape. For example, a third order field plane variation of overlay can be compensated for by designing the reflector MA-MT, 13, 14 such that pressure adjustments of the fluid in the channels 220, 320-324 induce a fourth order polynomial deformation profile in the reflective surface 210, 310. As previously discussed, in general the depth profiles 221, 222 and/or the cross-sectional shapes and/or the orientations of the cross-sectional shapes of the channels 220, 320-324 may be selected to at least partially determine the deformation profile of the reflective surface 210, 310 (and thereby the overlay of the lithographic apparatus LA). The deformation profile of the reflective surface 210, 310 may have a surface variation of about 100 pm or less. For example, channels having a diameter of about 2 mm located at a depth relative to the reflective surface of about 10 mm, this corresponds to a fluid pressure adjustment of about 1000 Pa. At lower depths, the required pressure change for the desired deformation of the reflective surface 210, 310 will be lower.

The controller 100 may be configured to adjust a pressure of the fluid by about 10 Pa or more. The controller 100 may be configured to adjust a pressure of the fluid by about 1 bar or less. The controller 100 may be configured to independently adjust the pressure of the fluid in at least two of the plurality of channels 320-324 to control the deformation of the reflective surface 310. That is, the controller 100 may apply first pressure adjustment in a first channel or a first group of channels and a different pressure adjustment in a second channel or second group of channels. This allows different deformation profiles to be applied to the reflective surface 310, thereby allowing greater control of the overlay of the lithographic apparatus LA. The controller 100 may comprise a plurality of sub-controllers (not shown). Different sub-controllers may be configured to adjust the pressure of the fluid in different channels or different groups of channels 320-324. For example, the pressure valve 250 may comprise a plurality of sub-valves (not shown) configured to act on different channels 320-324 and thereby independently control the pressures within different channels 320-324.

The deformation profile that is applied to the reflective surface 210, 310 by adjusting the pressure of the fluid in the channels 220, 320-324 may be designed using the depth profile of the channels as a sensitive parameter, because the mechanical stiffness of the portion of the body 200 located between the channel 220, 320-324 and the reflective surface 210, 310 may scale with the 3^{rd} power of the depth 221, 222 of the channel 220, 320-324 based on a second moment of area (i.e. an area moment of inertia). That is, with reference to FIG. 2, the material of the body 200 that is located between the channel 220 and the reflective surface 210 may be likened to a simply supported rectangular beam 260 that is supported by the channel 220. The simply supported rectangular beam 260 has a uniformly distributed load applied thereto by the pressure of the fluid in the channel 220. It is known in the field of mechanical engineering that the stiffness of a simply supported rectangular beam having a uniformly distributed load scales linearly with the second moment of area, and that the second moment of area scales with the 3^{rd} power of the height of said rectangular beam 260 (i.e., in this case, the depth 221, 222 of the channel 220). A diameter profile of the channels 220, 320-324 may be considered as an independent design parameter in designing the deformation profile of the reflective surface 210, 310 whilst ensuring that the cooling power of the fluid remains sufficiently uniform.

The correction profile may compensate for an overlay error that has greater than or equal to 3^{rd} order field plane variation, e.g. in an x-direction of the field plane. The depths of the channels 220, 320-324 relative to the reflective surface 210, 310 along the lengths of the channels and the cross-sectional shapes of the channels may be designed such that the controller 100 is operable to adjust the pressure of the fluid in the channels to apply at least a fourth order polynomial deformation profile to the reflective surface.

A dependency between the magnitude of the optical correction applied by the reflective surface 210, 310 and the pressure of the fluid in the channels 220, 320-324 may be assumed to be linear. Alternatively, the dependency between the magnitude of the optical correction applied by the reflective surface 210, 310 and the pressure of the fluid in the channels 220, 320-324 may be modelled numerically and calibrated in the lithographic apparatus LA by using the controller 100 to adjust the pressure of the fluid in the channels and measuring the effect on the wavefront of the reflected radiation B′ using an optical sensor 120 (e.g. an interferometric wavefront sensor). The controller 100 may be configured to determine the pressure adjustments needed to achieve the deformations of the reflective surface 210, 310 required to apply a correction profile of a desired magnitude to the patterned radiation beam B′. In general, increasing a pressure of the fluid in the channels 220, 320-324 may increase magnitude of the correction profile that is applied to the patterned radiation beam B′ by the reflective surface 210, 310.

Deformation of the reflective surface 210, 310 by the controller 100 may occur during projection of the patterned radiation beam B′. Deforming the reflective surface 210, 310 during projection of the patterned radiation beam B′ advantageously allows an overlay error present within a single target portion of the substrate W and/or an overlay error present between different target portions of the substrate W to be reduced whilst a pattern is being projected onto the substrate W. Alternatively, deformation of the reflective surface 210, 310 by the controller 100 may occur before projection of the patterned radiation beam B′ and the reflective surface may be held in its new shape during projection of the patterned radiation beam B′. The reflector MA-MT, 13, 14 and the controller 100 of the present disclosure may be used in combination with other optical element manipulators present in the projection system PS to control the overlay of the lithographic apparatus LA.

Specific overlay errors and corresponding applications of the reflector MA-MT, 13, 14 and the controller 100 of the present disclosure are discussed below.

The reflector MA-MT, 13, 14 and the controller 100 of the present disclosure may be used to apply a correction profile that corrects for overlay errors that are not caused by optical aberrations of the projection system PS (e.g. overlay errors caused by a deformation of a reticle MA and/or the substrate W, a change in temperature of the reticle MA and/or the substrate W, substrate processing effects, etc.) as well as overlay errors that are caused by optical aberrations of the lithographic apparatus LA. As previously discussed, an overlay error may be expressed in the form of field plane variations of the overlay error having different polynomial orders. A correction profile may be applied that adjusts the wavefront of radiation B′ reflecting from the reflective surface 210, 310 such that the correction profile compensates for at least 3^{rd} order field plane variations of an overlay error in an x-direction of the field plane by, for example, applying a correction profile that adjusts a Zernike of the wavefront reflecting from the reflective surface 210, 310.

A correction profile that is to be applied to a wavefront may be determined by determining an overlay error, determining a correction to the overlay error and converting the correction into a desired wavefront adjustment. It will be understood that each step of determining the overlay error, determining the correction and converting the correction into a desired wavefront adjustment may be performed in any of a number of appropriate ways. The correction profile (i.e. adjustments to the wavefront that reduce the overlay error) may then be determined, e.g. by determining a value of a polynomial, e.g. a Zernike, that induces a wavefront adjustment that reduces the overlay error. The correction profile may then be translated to a deformation of the reflective surface 210, 310 that is required to apply the correction profile to a wavefront reflecting from the reflective surface. The effect of an incremental adjustment of the pressure of the fluid in the channels 220, 320-324 on the wavefront of radiation B′ at different field plane positions may be measured and stored in a memory. The information stored in the memory may be referred to as reflector MA-MT, 13, 14 dependencies.

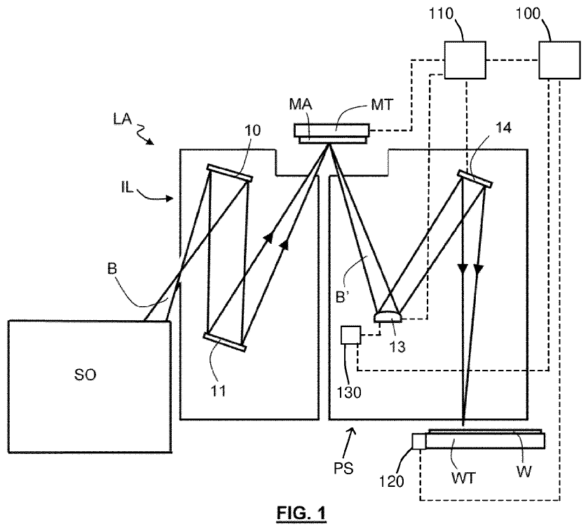

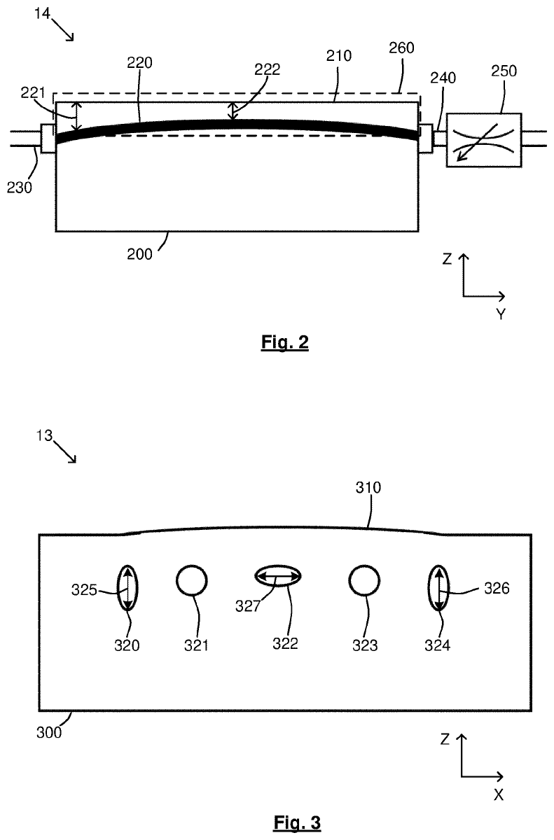

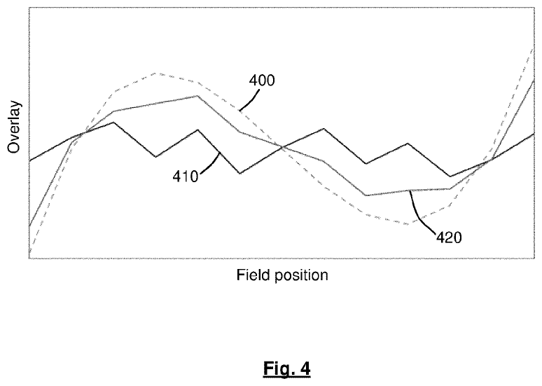

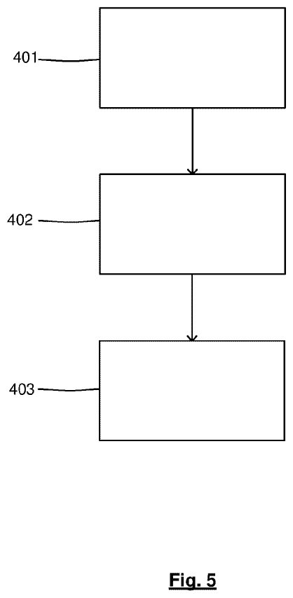

The reflector MA-MT, 13, 14 dependencies may be used when carrying out the translation of the correction profile to a deformation of the reflective surface 210, 310. For example, the correction profile and the reflector MA-MT, 13, 14 dependencies may be provided to an algorithm that is configured to determine a pressure adjustment of the fluid in the channels 220, 320-324 by the controller 100 that best applies the correction profile to a wavefront. The algorithm may be configured to reduce or minimize a residual wavefront (i.e. to reduce a difference between a desired “set-point” wavefront and an actual “realized” wavefront). The algorithm may, for example, be a least squares algorithm. FIG. 4 shows a graph of that demonstrates the ability 420 of the reflector and controller of the present disclosure to control a third order field plane variation of overlay 400 compared to a known method 410. As can be seen, the set-point overlay variation with field position takes the form of a third order polynomial 400. The known method 410 solely relies upon rigid mechanical movement of the reflective surface relative to the radiation beam and provides a poor fit to the set-point overlay 400. The performance 420 of the reflector MA-MT-13, 14 and controller 100 of the present disclosure combined with rigid mechanical movement of the reflective surface 210, 310 provides a much better fit to the overlay set-point 400.

Other types of algorithm may be used, e.g. algorithms that account for limitations of deformation of the reflective surface 210, 310. The pressure of the fluid in the channels 220, 320-324 may then be adjusted such that portions of the reflective surface 210, 310 are at the relative positions needed to apply the correction profile to the wavefront. A wavefront incident on the deformed reflective surface 210, 310 is adjusted on reflection from the reflective surface such that the determined overlay error is reduced.

In some device manufacturing methods, the substrate W may be processed between different lithographic exposures. That is, one layer of the substrate W may be exposed to patterned radiation B′ and then the substrate W may be removed from the lithographic apparatus LA to undergo substrate processing such as, for example, polishing, etching, baking, etc. After substrate processing, the substrate W may be inserted into the same lithographic apparatus LA (or a different lithographic apparatus) and another layer of the substrate W may be exposed to a patterned radiation beam B′. Substrate processing may result in overlay errors. Overlay errors resulting from substrate processing may be referred to as substrate processing effects. For example, etching a layer of the substrate W may alter stresses acting within the substrate (e.g. stresses across scribe lanes of a substrate) and the positions of features present on the substrate may change from their intended positions as a result of the changing stresses within the substrate. As another example, baking of the substrate W may cause thermal deformation of the substrate which may result in the positions of features present on the substrate changing from their intended positions.

The correction profile may correct for substrate processing effects. For example, a first layer of a substrate W may be exposed in a first lithographic exposure. The substrate W may be removed from the lithographic apparatus LA and undergo substrate processing. The substrate W may then be re-inserted into the lithographic apparatus LA and the next layer of the substrate may undergo a second lithographic exposure. An overlay error between the first layer and the second layer may be measured, e.g. by carrying out a lithographic exposure in resist on the substrate W and measuring an overlay error of projected features such as, for example, product features and/or alignment features present on the substrate W. A correction profile may be determined that reduces the measured overlay error when the correction profile is applied to the radiation beam B′ via deformation of the reflective surface 210, 310 of the reflector MA-MT, 13, 14 by the controller 100. The correction profile may then be applied to the radiation beam B′ in future exposures to reduce the overlay error. Different correction profiles may be determined for different combinations of lithographic apparatus LA and substrate processing.

The lithographic apparatus LA may comprise a support structure MT configured to support the reticle MA. By supporting the reticle MA, the support structure MT may induce an unwanted deformation of the reticle. For example, the reticle MA may be clamped to the support structure MT, e.g. via vacuum clamping or electrostatic clamping. The act of clamping the reticle MA to the support structure MT may deform the reticle from its resting shape. A deformation of the reticle MA may introduce an overlay error. The correction profile may correct for a deformation of the reticle MA resulting from the support structure MT supporting the reticle.

During a lithographic exposure the temperature of the reticle MA may change. The reticle MA may undergo thermal deformation as a result of the reticle changing temperature. For example, the reticle MA may absorb energy from the radiation beam B that is incident on the reticle and the temperature of the reticle may increase. The reticle MA may undergo thermal expansion when the temperature of the reticle increases. Thermal deformation of the reticle MA may introduce an overlay error. The correction profile may correct for a change in temperature of the reticle MA. For example, a computer model may be used to predict an overlay error resulting from the reticle MA changing temperature. The computer model may be calibrated by comparing its results with the results of a lithographic exposure of a substrate W comprising a resist. The results of the computer model may be used to determine a correction profile that is configured to reduce the overlay error. Alternatively, known alignment sensors such as, for example, one or more interferometric wavefront sensors may be used to measure wavefront aberrations. The measured wavefront aberrations may then be used to determine the correction profile. The correction profile may be applied to a patterned radiation beam B′ via deformation of the reflective surface 210, 310 by the controller 100. The reflector MA-MT, 13, 14 and controller 100 of the present disclosure may be used to reduce an overlay error caused by a change in temperature of the reticle MA.

The lithographic apparatus LA may comprise a substrate table WT configured to hold the substrate W. For example, the substrate table WT may comprise burls that are configured to support the substrate W. The burls may impart a force on the substrate W that causes the substrate to deform. Deformation of the substrate W may introduce an overlay error. Different substrate tables WT may cause different deformations of the substrate W. Deformation caused by a substrate table WT holding the substrate W may change through the lifetime of a substrate table. For example, burls may deteriorate over time and consequently the forces the burls impart to the substrate W may change over time.

The correction profile may correct for a deformation of the substrate W resulting from the substrate table WT holding the substrate. For example, a topography measurement system may be used to measure a topography of the substrate W when the substrate is held by the substrate table WT. The measured topography of the substrate W may be provided to a computer model that is configured to convert the measured topography to a predicted overlay error. The predicted overlay error may be used to determine a correction profile. Alternatively, overlay errors resulting from a deformation of the substrate W may be determined by carrying out a lithographic exposure in resist on the substrate and measuring an overlay error of projected features such as, for example, product features and/or alignment features present on the substrate. The measured overlay error may be used to determine a correction profile. The reflective surface 210, 310 may be deformed by the controller 100 to reduce an overlay error caused by deformation of the substrate W resulting from the substrate table WT holding the substrate.

During a lithographic exposure the temperature of the substrate W may change. The substrate W may undergo thermal deformation as a result of the substrate changing temperature. For example, the substrate W may absorb energy from the patterned radiation beam B′ that is incident on the substrate and the temperature of the substrate may increase. The substrate W may undergo thermal expansion and deform when the temperature of the substrate increases. Deformation of the substrate W may cause an overlay error. The correction profile may correct for a change in temperature of the substrate W. The reflector MA-MT, 13, 14 and controller 100 of the present disclosure may be used to reduce an overlay error caused by a change in temperature of the substrate W.

FIG. 5 shows a flowchart of a method in accordance with the present disclosure. The method comprises a first step 401 of providing a flow of fluid through a channel 220, 320-324 formed in a body 200, 300 on which a reflective surface 210, 310 of a lithographic apparatus LA is arranged.

The method comprises a second step 402 of adjusting a pressure of the fluid to control a deformation of the reflective surface 210, 310 and thereby control an overlay of the lithographic apparatus LA.

The method comprises a third step 403 of reflecting radiation B′ from the reflective surface 210, 310.

A depth of the channel 220, 320-324 may vary relative to the reflective surface 210, 310 along a length of the channel. The channel 220, 320-324 may be one of a plurality of channels formed in the body 200, 300 for conveying the fluid. The method may comprise providing the flow of fluid through at least two channels 220, 320-324 having different cross-sectional shapes. The method may comprise providing the flow of fluid through at least two channels 220, 320-324 having cross-sectional shapes that have different orientations relative to the reflective surface 210, 310. The method may comprise adjusting the pressure of the fluid in the channels 220, 320-324 to apply at least a fourth order polynomial deformation profile to the reflective surface 210, 310. The reflective surface 210, 310 may be at least partially spherical. The method may comprise adjusting a position of the reflective surface 210, 310.

A method of manufacturing the body 200, 300 of the reflector MA-MT, 13, 14 of the lithographic apparatus LA may comprise performing laser ablation to form the channel 220, 320-324 in the body of the reflector. Using laser ablation to form the channels 220, 320-324 advantageously provides fine control of the depth profile and cross-sectional shape of the channel, thereby allowing a greater variety of depth profiles and cross-sectional shapes to be formed. For example, channels 220, 320-324 having more ‘freeform’ shapes, such as 4^{th} order polynomial shapes, may be accurately formed using laser ablation compared to known methods of forming the channels (e.g. to mechanically bore a channel in the body 200, 300). Performing laser ablation to form the channels 220, 320-324 may comprise varying a depth of the channels 220, 320-324 relative to the reflective surface along a length of the channels 220, 320-324. The method of manufacturing the body 200, 300 of the reflector MA-MT, 13, 14 may comprise performing laser ablation to form at least two channels 220, 320-324 having different cross-sectional shapes. The method of manufacturing the body 200, 300 of the reflector MA-MT, 13, 14 may comprise performing laser ablation to form at least two channels 220, 320-324 having cross-sectional shapes that have different orientations relative to the reflective surface.

The method of using a reflector MA-MT, 13, 14 and a controller 100 as described herein to correct for overlay errors may be retrofitted to existing lithographic apparatus LA without requiring a significant redesign of the lithographic apparatus. For example, a reflector MA-MT, 13, 14 in accordance with the present disclosure may replace a previous reflector, and a controller 100 of the lithographic apparatus LA may be reconfigured to apply pressure adjustments to fluid in the channels 220, 320-324 of the reflector MA-MT, 13, 14. The reflector MA-MT, 13, 14 and controller 100 may then be used to carry out the methods of correcting overlay errors described herein. The reflective surface 210, 310 may be deformed by the controller to apply different correction profiles at any desired frequency. For example, a correction profile may be applied to the reflective surface 210, 310 per lot of substrates W, per substrate, per target portion of a substrate or during exposure of a single target portion of a substrate. In general, the overlay error that is reduced by use of the reflector MA-MT, 13, 14 and controller 100 may be determined via direct measurement (e.g. using a detector system 120), indirect measurement (e.g. performing a lithographic exposure in a resist and analysing the resist) and/or prediction (e.g. by inputting data into a computer model and executing the computer model).

Although specific reference may be made in this text to the use of lithographic apparatus LA in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

Further embodiments are disclosed in the subsequent list of numbered clauses:
1. A lithographic apparatus comprising:
a reflector for reflecting radiation comprising a body, a reflective surface arranged on the body, and a channel formed in the body for conveying a fluid; and,
a controller configured to adjust a pressure of the fluid in the channel to control a deformation of the reflective surface and thereby control an overlay of the lithographic apparatus.
2. The lithographic apparatus of clause 1, wherein a depth of the channel relative to the reflective surface varies along a length of the channel.
3. The lithographic apparatus of any preceding clause, wherein the channel is one of a plurality of channels formed in the body for conveying the fluid, and wherein at least two of the channels have different cross-sectional shapes,
and/OR
wherein cross-sectional shapes of at least two of the channels have different orientations relative to the reflective surface.
4. The lithographic apparatus of clause 2 and clause 3, wherein depths of the channels relative to the reflective surface along lengths of the channels and the cross-sectional shapes of the channels are designed such that the controller is operable to adjust the pressure of the fluid in the channels to apply at least a fourth order polynomial deformation profile to the reflective surface.
5. The lithographic apparatus of clause 3 or clause 4, wherein the controller is configured to independently adjust the pressures of the fluid in at least two of the plurality of channels to control the deformation of the reflective surface.
6. The lithographic apparatus of any preceding clause, comprising:
an inlet conduit configured to provide the fluid to the channel;
an outlet conduit configured to receive the fluid from the channel; and,
a flow restrictor arranged on the outlet conduit.
7. The lithographic apparatus of clause 6, wherein the flow restrictor comprises a pressure valve and the controller is configured to control the pressure valve to adjust the pressure of the fluid in the channel.
8. The lithographic apparatus of any preceding clause, comprising an optical sensor configured to detect at least a portion of the radiation reflected by the reflective surface, wherein the controller is configured to receive optical measurement data from the optical sensor and use the optical measurement data to control the deformation of the reflective surface.
9. The lithographic apparatus of any preceding clause, comprising an actuator configured to adjust a position and/or an orientation of the reflector.
10. The lithographic apparatus of any preceding clause comprising:
an illumination system configured to condition the radiation beam;
a support structure constructed to support a patterning device, the patterning device being capable of imparting the radiation beam with a pattern in its cross-section to form a patterned radiation beam;
a substrate table constructed to hold a substrate; and,
a projection system configured to project the patterned radiation beam onto the substrate, wherein the reflector is a mirror in the projection system.
11. The lithographic apparatus of any of clauses 1-9 comprising:
an illumination system configured to condition the radiation beam;
a support structure constructed to support a patterning device, the patterning device being capable of imparting the radiation beam with a pattern in its cross-section to form a patterned radiation beam;
a substrate table constructed to hold a substrate; and,
a projection system configured to project the patterned radiation beam onto the substrate,
wherein the reflective surface forms part of the patterning device and the body forms part of the support structure.
12. A method comprising:
providing a flow of fluid through a channel formed in a body on which a reflective surface of a lithographic apparatus is arranged;
adjusting a pressure of the fluid to control a deformation of the reflective surface and thereby control an overlay of the lithographic apparatus; and,
reflecting radiation from the reflective surface. 13. The method of clause 12, wherein a depth of the channel relative to the reflective surface varies along a length of the channel.
14. The method of clause 12 or clause 13, wherein the channel is one of a plurality of channels formed in the body for conveying the fluid,
wherein the method comprises providing the flow of fluid through at least two channels having different cross-sectional shapes,
and/or
wherein the method comprises providing the flow of fluid through at least two channels having cross-sectional shapes that have different orientations relative to the reflective surface.
15. The method of clause 13 and clause 14, comprising adjusting the pressure of the fluid in the channels to apply at least a fourth order polynomial deformation profile to the reflective surface.
16. The method of clause 14 or clause 15, comprising independently adjusting the pressures of the fluid in at least two of the plurality of channels to control the deformation of the reflective surface.
17. The method of any of clauses 12 to 16, comprising adjusting a position and/or an orientation of the reflective surface.
18. A method of manufacturing the body of the reflector of the lithographic apparatus of any of clauses 1 to 11, comprising performing laser ablation to form the channel.
19. The method of clause 18, wherein performing laser ablation to form the channel comprises varying a depth of the channel relative to the reflective surface along a length of the channel.
20. The method of clause 18 or clause 19, comprising performing laser ablation to form at least two channels having different cross-sectional shapes,
and/or
performing laser ablation to form at least two channels having cross-sectional shapes that have different orientations relative to the reflective surface.

1. A lithographic apparatus comprising:
a reflector configured to reflect radiation, the reflector comprising:
a body,
a reflective surface arranged on the body, and
a channel formed in the body for conveying a fluid; and
a controller configured to adjust a pressure of the fluid in the channel to control a deformation of the reflective surface to control an overlay of the lithographic apparatus.

2. The apparatus of claim 1, wherein a depth of the channel relative to the reflective surface varies along a length of the channel.

3. The apparatus of claim 1, wherein the channel is one of a plurality of channels formed in the body to convey the fluid, and
wherein at least two of the channels have different cross-sectional shapes and/or wherein cross-sectional shapes of at least two of the channels have different orientations relative to the reflective surface.

4. The apparatus of claim 2, wherein depths of the channels relative to the reflective surface along lengths of the channels and the cross-sectional shapes of the channels are designed such that the controller is operable to adjust the pressure of the fluid in the channels to apply at least a fourth order polynomial deformation profile to the reflective surface.

5. The lithographic apparatus of claim 3, wherein the controller is configured to independently adjust the pressures of the fluid in at least two of the plurality of channels to control the deformation of the reflective surface.

6. The apparatus of claim 1, further comprising:
an inlet conduit configured to provide the fluid to the channel;
an outlet conduit configured to receive the fluid from the channel; and
a flow restrictor arranged on the outlet conduit.

7. The apparatus of claim 6, wherein the flow restrictor comprises a pressure valve and the controller is configured to control the pressure valve to adjust the pressure of the fluid in the channel.

8. The lithographic apparatus of claim 1, further comprising an optical sensor configured to detect at least a portion of the radiation reflected by the reflective surface, wherein the controller is configured to receive optical measurement data from the optical sensor and use the optical measurement data to control the deformation of the reflective surface.

9. The apparatus of claim 1, further comprising an actuator configured to adjust a position and/or an orientation of the reflector.

10. The lithographic apparatus of claim 1, further comprising:
an illumination system configured to condition the radiation beam;
a support structure constructed to support a patterning device, the patterning device being capable of imparting the radiation beam with a pattern in its cross-section to form a patterned radiation beam;
a substrate table constructed to hold a substrate; and
a projection system configured to project the patterned radiation beam onto the substrate, wherein the reflector is a mirror in the projection system.

11. The apparatus of any of claim 1, further comprising:
an illumination system configured to condition the radiation beam;
a support structure constructed to support a patterning device, the patterning device being capable of imparting the radiation beam with a pattern in its cross-section to form a patterned radiation beam;
a substrate table constructed to hold a substrate; and
a projection system configured to project the patterned radiation beam onto the substrate, wherein the reflective surface forms part of the patterning device and the body forms part of the support structure.

12. A method comprising:
providing a flow of fluid through a channel formed in a body on which a reflective surface of a lithographic apparatus is arranged;
adjusting a pressure of the fluid to control a deformation of the reflective surface to control an overlay of the lithographic apparatus; and reflecting radiation from the reflective surface.

13. A method of manufacturing the body of the reflector of the lithographic apparatus of claim 1, the method comprising performing laser ablation to form the channel.

14. The method of claim 13, wherein performing laser ablation to form the channel comprises varying a depth of the channel relative to the reflective surface along a length of the channel.

15. The method of claim 13, comprising performing laser ablation to form at least two channels having different cross-sectional shapes, and/or to form at least two channels having cross-sectional shapes that have different orientations relative to the reflective surface.

16. The method of claim 12, wherein the channel is one of a plurality of channels formed in the body to convey the fluid and further comprising independently adjusting pressures of the fluid in at least two of the plurality of channels to control the deformation of the reflective surface.

17. The method of claim 12, comprising adjusting the pressure of the fluid in the channels to apply at least a fourth order polynomial deformation profile to the reflective surface.

18. The method of claim 12, further comprising adjusting a position and/or an orientation of the reflective surface.

19. The method of claim 12, further comprising:
detecting at least a portion of the radiation reflected by the reflective surface to obtain optical measurement data; and
using the optical measurement data to control the deformation of the reflective surface.

20. The method of claim 12, further comprising:
imparting a pattern to a radiation beam to form a patterned radiation beam; and
projecting the patterned radiation beam onto a substrate using a projection system,
wherein the reflector is a mirror in the projection system.
